(19) United States
(12) Patent Application Publication
(10) Pub. No.: US 2008/0318169 A1
(43) Pub. Date: Dec. 25, 2008

(54) PATTERN FORMING METHOD

(76) Inventor: Shuichi TANIGUCHI, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/113,345

(22) Filed: May 1, 2008

(30) Foreign Application Priority Data
Jun. 21, 2007 (JP) 2007-163579

(51) Int. Cl. G03F 7/20

(52) U.S. Cl. 430/323

(57) ABSTRACT

A pattern forming method according to an embodiment of the present invention includes: forming a plurality of pole-like structures above a film to be processed; forming a sidewall film on each of sidewalls of the plurality of pole-like structures so as to form a depression portion in a region surrounded by corresponding ones of the plurality of pole-like structures; removing the sidewall film formed above each of the plurality of pole-like structures and in a bottom portion of the depression portion, respectively, by performing etching; and selectively etching the plurality of pole-like structures with the sidewall film being left.

### CROSS-REFERENCE TO RELATED APPLICATIONS

This application is based upon and claims the benefit of priority from prior Japanese Patent Application No. 2007-163579, filed on Jun. 21, 2007, the entire contents of which are incorporated herein by reference.

### BACKGROUND

There is known a pattern forming method of, after a pattern, having holes, formed from a resist is formed on a film to be processed by utilizing a lithography method, depositing a sidewall film on an inner wall of the pattern, thereby forming a pattern having holes each having a dimension beyond the limits of the lithography method for the purpose of forming a microscopical hole pattern in processes for fabricating a semiconductor device.

A method of fabricating a semiconductor device in which after a recess portion is formed in an organic insulating film formed on a film to be processed, an upper film which reacts with an organic insulating film when being heated is formed on the organic insulating film having the recess portion formed therein, and a heating treatment is performed for the upper film to form a reaction layer which grows due to the reaction with the organic insulating film on a side surface of the recess portion, thereby reducing a dimension of the recess portion is described in Japanese Patent KOKAI No. 2007-5379.

However, although with the conventional pattern forming method and method of fabricating a semiconductor device, the dimension of the hole in the hole pattern or the dimension of the recess portion is reduced, neither the number of holes, per unit area, in the hole pattern nor the number of recess portions per unit area changes.

### BRIEF SUMMARY

An embodiment of the present invention provides a pattern forming method including: forming a plurality of pole-like structures above a film to be processed; forming a sidewall film on each of sidewalls of the plurality of pole-like structures so as to form a depression portion in a region surrounded by corresponding ones of the plurality of pole-like structures; removing the sidewall film formed above each of the plurality of pole-like structures and in a bottom portion of the depression portion, respectively, by performing etching; and selectively etching the plurality of pole-like structures with the sidewall film being left.

### BRIEF DESCRIPTION OF THE DRAWINGS

FIG. 1A is a top plan view showing a first step of a pattern forming method according to an embodiment of the present invention;

FIG. 1B is a longitudinal cross sectional view taken on line A-A′ of FIG. 1A;

FIG. 2 is a longitudinal cross sectional view showing a second step following the first step of the pattern forming method according to the embodiment of the present invention;

FIG. 3 is a longitudinal cross sectional view showing a third step following the second step of the pattern forming method according to the embodiment of the present invention;

FIG. 4 is a longitudinal cross sectional view showing a fourth step following the third step of the pattern forming method according to the embodiment of the present invention;

FIG. 5 is a longitudinal cross sectional view showing a fifth step following the fourth step of the pattern forming method according to the embodiment of the present invention;

FIG. 6 is a longitudinal cross sectional view showing a sixth step following the fifth step of the pattern forming method according to the embodiment of the present invention;

FIG. 7A is a top plan view showing a halfway step of a seventh step following the six step of the pattern forming method according to the embodiment of the present invention;

FIG. 7B is a longitudinal cross sectional view showing a halfway step of the seventh step of the pattern forming method according to the embodiment of the present invention;

FIG. 8A is a top plan view showing a state after completion of the seventh step of the pattern forming method according to the embodiment of the present invention;

FIG. 8B is a longitudinal cross sectional view showing the state after completion of the seventh step of the pattern forming method according to the embodiment of the present invention;

FIG. 9A is a top plan view showing an eighth step following the seventh step of the pattern forming method according to the embodiment of the present invention;

FIG. 9B is a longitudinal cross sectional view showing the eight step of the pattern forming method according to the embodiment of the present invention;

FIG. 10A is a top plan view showing a ninth step following the eight step of the pattern forming method according to the embodiment of the present invention;

FIG. 10B is a longitudinal cross sectional view showing the ninth step of the pattern forming method according to the embodiment of the present invention;

FIG. 11A is a top plan view showing a tenth step following the ninth step of the pattern forming method according to the embodiment of the present invention; and

FIG. 11B is a longitudinal cross sectional view showing the tenth step of the pattern forming method according to the embodiment of the present invention.

### DETAILED DESCRIPTION

### Embodiment

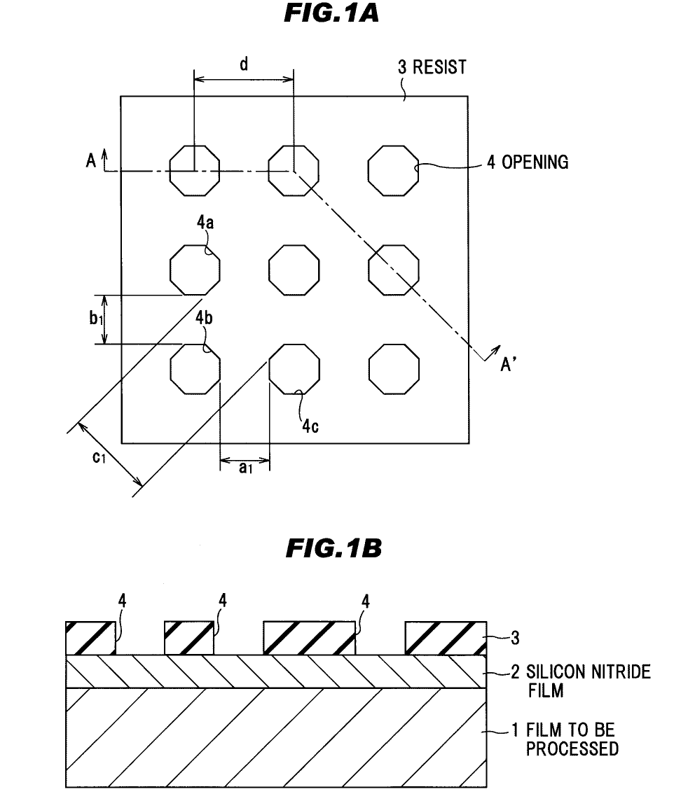

FIG. 1A is a top plan view showing a first step of a pattern forming method according to an embodiment of the present invention, and FIG. 1B is a longitudinal cross sectional view taken on line A-A′ of FIG. 1A.

As shown in FIG. 1B, a silicon nitride film 2 as a first material film is deposited on a film 1 to be processed formed from a silicon oxide film by utilizing a Chemical Vapor Deposition (CVD) method. Also, a resist 3 is applied to an upper surface of the silicon nitride film 2. Subsequently, a pattern having a plurality of openings 4 each having a predetermined shape is formed in the resist 3 by utilizing a lithography method.

Each of the plurality of openings 4 formed on the silicon nitride film 2, as shown in FIG. 1A, has a hole shape having approximately a regular octagon as an example. For example, each of the plurality of openings 4 is formed in a dimension such that a circle having a diameter of 60 nm approximately contacts each of sides of the corresponding one of the plurality of openings 4 from the inner side. Moreover, the plurality of openings 4 are formed on the silicon nitride film 2 so as to be disposed substantially at even intervals in different two directions. For example, the plurality of openings 4 are formed on the silicon nitride film 2 so as to be disposed in a matrix.

That is to say, the plurality of openings 4 are formed on the silicon nitride film 2 along a first direction and a second direction vertical to the first direction. Also, the plurality of openings 4 are formed on the silicon nitride film 2 so that a pitch between one opening 4 and another opening 4 located adjacent to the one opening 4 in the first direction becomes equal to that between the one opening 4 and still another opening 4 located adjacent to the one opening 4 in the second direction. As an example, the plurality of openings 4 are formed so that the pitch, d, between the one opening 4 and the another opening 4 adjacent thereto is set at 120 nm.

In addition, a spacing, a1, between one opening 4 (for example, an opening 4b) and another opening 4 (for example, an opening 4c), and a spacing, b1, between the one opening 4 and still another opening 4 (for example, an opening 4a) are set so that a ratio of the spacing a1 to the spacing b1 becomes 1:1. For example, the plurality of openings 4 (for example, the opening 4a, the opening 4b, the opening 4c, etc.) are formed in the resist 3 so that each of the spacing al and the spacing b1 becomes 60 nm. Here, the opening 4a, the opening 4b, the opening 4c, etc. are disposed in a matrix, and thus the opening 4c is located in a diagonal position with respect to the opening 4a. Also, when a spacing between the opening 4c and the opening 4a is c1, the spacing c1 is set more widely than each of the spacing a1 and the spacing b1.

It is noted that the film 1 to be processed may be an insulating film disposed on a substrate which is mainly made of a semiconductor such as silicon, and can also, for example, be formed from a Low-k film having a relative dielectric constant of 3.3 or less instead of being formed from the silicon oxide film. An inorganic insulating film such as a carbon-containing SiO₂ (SiOC) film, a boro-silicate glass (BGS) film, or a porous silica film, an amorphous carbon film, a polymer film such as a polyimide system film or a fluorine resin system film, or an organic insulating film such as a methyl group-containing SiO₂ (methylsilsesquioxane: MSQ) film can be used as the Low-k film.

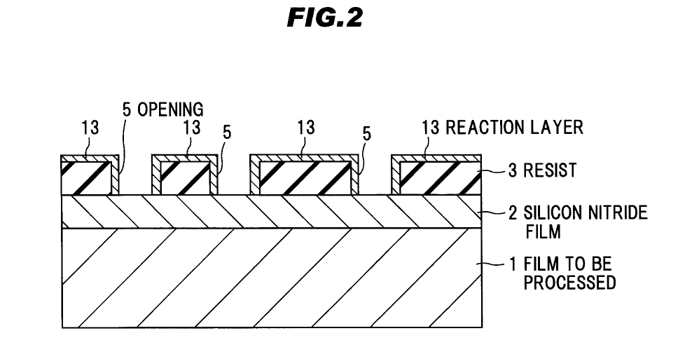

FIG. 2 is a longitudinal cross sectional view showing a second step following the first step of the pattern forming method according to the embodiment of the present invention.

In the second step, an organic material as a pattern shrink material which is hardened due to the acting of an acid component in the resist 3 is applied to the surface of the resist 3 having the plurality of openings 4 formed therein. After completion of the application of the organic material to the surface of the resist 3, a heating treatment is performed for the resist 3 at a predetermined temperature for a predetermined time. Performing the heat treatment for the resist 3 results in that the organic material applied to the surface of the resist 3 is hardened, thereby forming a reaction layer 13. Subsequently, the organic material which is not hardened by performing the heating treatment is rinsed and removed in water. As a result, the reaction layer 13 is formed to cover the surface of the resist 3 having the openings 4 formed therein, and thus openings 5 each having a dimension to which the dimension of each of the openings 4 when viewed from the upper part is reduced are formed on the silicon nitride film 2.

As an example, the reaction layer 13 is formed to cover the surface of the resist 3 so as to be 10 nm thick. Therefore, the dimension of the opening 5 when viewed from the upper part becomes one such that a circle having a diameter of 40 nm approximately contacts each of the sides of the opening 5 from the inner side.

Here, the pattern shrink material is an organic material containing therein a solvent composed of a mixed liquid of a hydrosoluble resin such as polyvinyl alcohol, a hydrosoluble crosslinking material such as a melamine derivative, and water or a hydrosoluble organic solvent such as isopropyl alcohol. When after the pattern shrink material is applied to the surface of the resist 3, a heating treatment and/or an exposure treatment is performed for the resist 3 having the pattern shrink material applied thereto, an acid component generated from the resist 3, and an acid component existing in the resist diffuse into the pattern shrink material.

Also, the hydrosoluble resin and the hydrosoluble crosslinking material which the pattern shrink material contains therein initiate a cross-linking reaction due to the acting of the acid components which have diffused into the pattern shrink material, thereby forming the reaction layer 13. Forming the reaction layer 13 so as to cover the surface of the resist 3 results in that the openings 5 each having the dimension to which the dimension of each of the openings 4 is reduced are formed. It is noted that after the pattern shrink material is applied to the surface of the resist 3, the temperature and time required for the heating treatment performed for the resist 3 are controlled, which results in that a thickness of the reaction layer 13 can be controlled to attain a desired thickness.

Note that, a process may also be adopted such that etch back is performed after a silicon oxide film, a polysilicon film or the like having predetermined thickness, is disposed so as to cover the surface of the resist 3 to form a sidewall on each of side surfaces of the openings 4 of the resist 3, thereby obtaining the openings 5 each having the dimension to which the dimension of each of the openings 4 is reduced on the silicon nitride film 2.

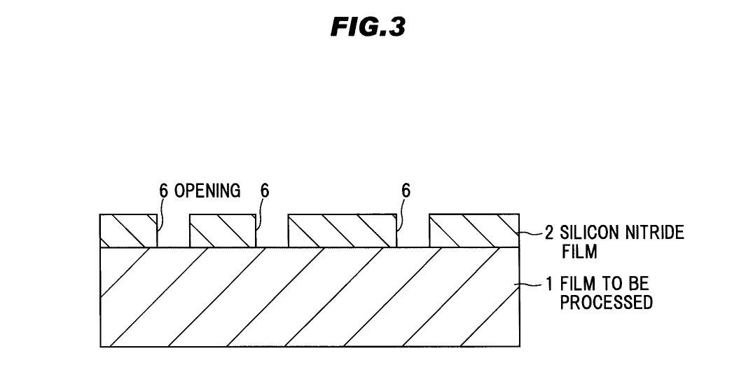

FIG. 3 is a longitudinal cross sectional view showing a third step following the second step of the pattern forming method according to the embodiment of the present invention.

In the third step, the silicon nitride film 2 is dry-etched by utilizing a Reactive Ion Etching (RIE) method using gas such as CH₂F₂ by using a plurality of openings 5 formed in the second step as a mask. Subsequently, the resist 3 having the surface which the reaction film 13 is formed so as to cover is removed from the surface of the silicon nitride film 2 by performing down flow type plasma ashing processing using O₂ or the like. As a result, a pattern of the plurality of openings 5 formed in the resist 3 through the reaction layer 13 is transferred to the silicon nitride film 2, thereby forming a plurality of openings 6 on the film 1 to be processed.

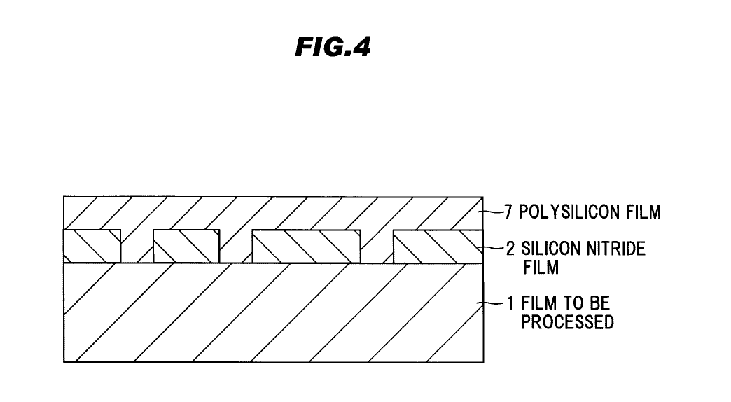

FIG. 4 is a longitudinal cross sectional view showing a fourth step following the third step of the pattern forming method according to the embodiment of the present invention.

In the fourth step, a polysilicon film 7, as a second material film, having a predetermined thickness is deposited so as to cover upper surfaces portions of the film 1 to be processed which are exposed to the outside through the plurality of openings 6, respectively, and the surface of the silicon nitride film 2 having the plurality of opening 6 formed therein by utilizing a deposition method such as the CVD method.

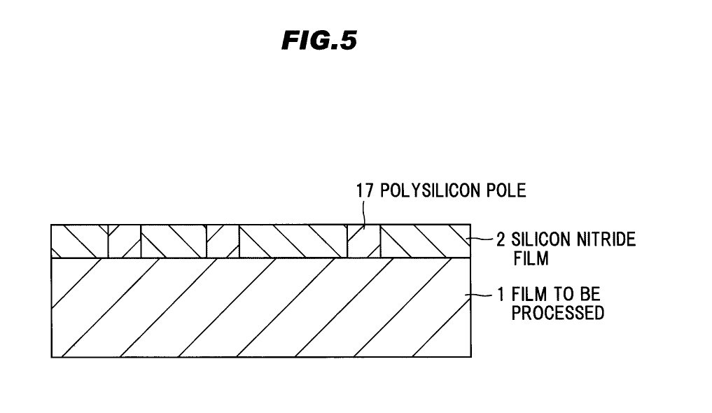

FIG. 5 is a longitudinal cross sectional view showing a fifth step following the fourth step of the pattern forming method according to the embodiment of the present invention.

In the fifth step, the polysilicon film 7 which is deposited so as to cover the upper surface portions of the film 1 to be processed which are exposed to the outside through the plurality of openings 6, respectively, and the surface of the silicon nitride film 2 having the plurality of opening 6 formed therein is planarized by performing Chemical Mechanical Polishing (CMP) processing or the like. In this case, the planarization is performed for the polysilicon film 7 until surfaces of portions of the polysilicon film 7 filled in the plurality of openings 6, respectively, are exposed to the outside. Here, when the polysilicon film 7 deposited so as to cover the surface of the silicon nitride film 2 is removed, the portions of the polysilicon film 7 filled in the plurality of openings 6 become polysilicon poles 17, as pole-like structures, respectively, each of which is made of polysilicon.

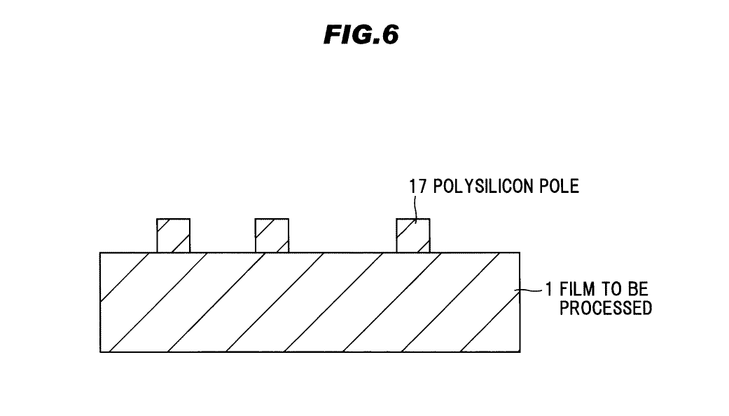

FIG. 6 is a longitudinal cross sectional view showing a sixth step following the fifth step of the pattern forming method according to the embodiment of the present invention.

In the sixth step, the silicon nitride film 2 formed on the film 1 to be processed is selectively removed by utilizing the RIE method using gas such as CH₃F. That is to say, in the sixth step, the silicon nitride film 2 formed on the film 1 to be processed is selectively removed by utilizing the RIE method, while the polysilicon poles 17 formed so as to be filled in the plurality of openings 6, respectively, are left as they are. After completion of the sixth step, a plurality of regularly octagonal poles 17 each being made of polysilicon are left on the film 1 to be processed.

It is noted that in the sixth step, the silicon nitride film 2 may be selectively wet-etched by using an etchant with which an etching rate is higher in the silicon nitride than in polysilicon.

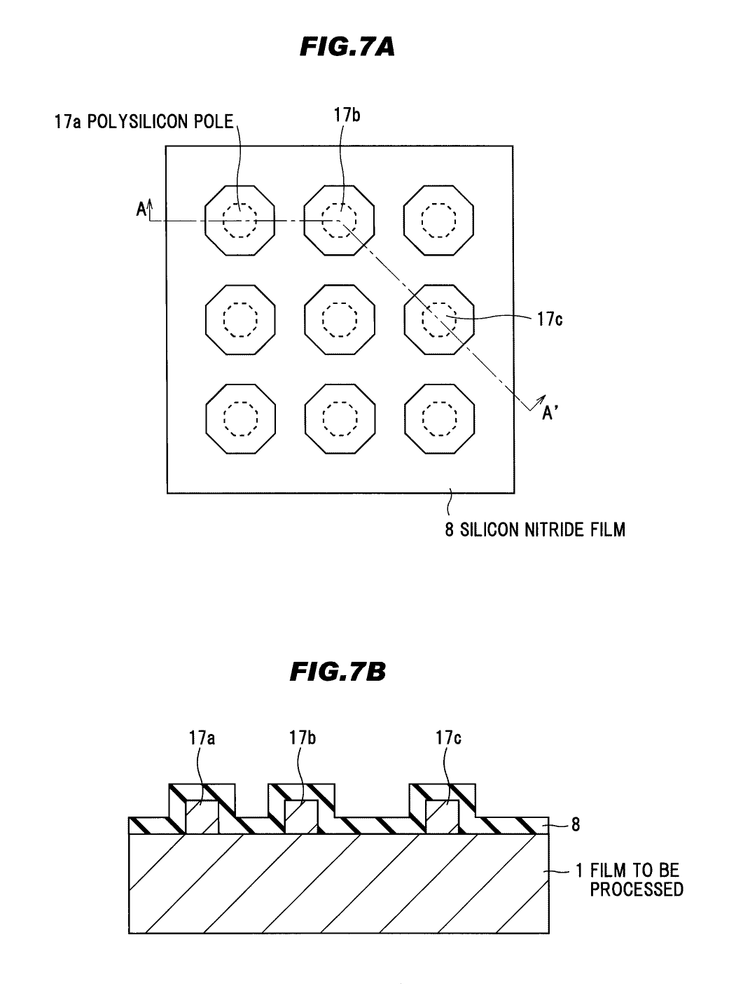

FIG. 7A is a top plan view showing a halfway step of a seventh step following the six step of the pattern forming method according to the embodiment of the present invention, and FIG. 7B is a longitudinal cross sectional view showing a halfway step of the seventh process of the pattern forming method according to the embodiment of the present invention.

A silicon nitride film 8 is uniformly formed as a sidewall film so as to cover each of sidewalls and upper surfaces of the polysilicon poles 17 each being formed from the polysilicon film 7, and an upper surface of the film 1 to be processed by utilizing a deposition method such as the CVD method. That is to say, as shown in FIGS. 7A and 7B, the silicon nitride film 8 is deposited so as to cover each of the sidewalls and upper surfaces of the polysilicon poles 7, and the upper surface of the film 1 to be processed.

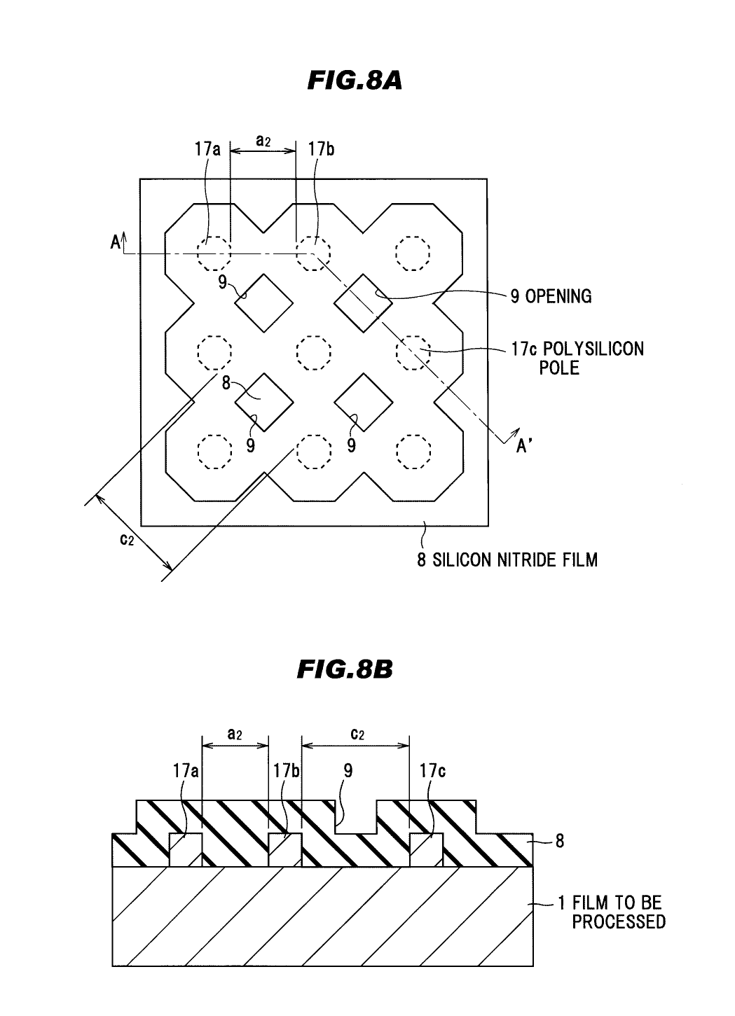

FIG. 8A is a top plan view showing a state after completion of the seventh step of the pattern forming method according to the embodiment of the present invention, and FIG. 8B is a longitudinal cross sectional view showing the state after completion of the seventh step of the pattern forming method according to the embodiment of the present invention.

A thickness of the silicon nitride film 8 formed after completion of the seventh step is one such that the silicon film 8 formed on the sidewall of one polysilicon pole 17a, and the silicon nitride film 8 formed on the sidewall of another polysilicon pole 17b located adjacent to the one polysilicon pole 17a contact each other. Moreover, the thickness of the silicon nitride film 8 formed after completion of the seventh step is one such that the silicon nitride film 8 formed on the sidewall of still another polysilicon pole 17c located adjacent to the polysilicon pole 17b in a direction, as a third direction, at 45° with a straight line connecting a center of the polysilicon pole 17a and a center of the polysilicon pole 17b, and the silicon nitride film 8 formed on the sidewall of the polysilicon pole 17b do not contact each other.

That is to say, the thickness of the silicon nitride film 8 formed on the sidewall of the polysilicon pole 17 is not smaller than ½ of a spacing, a2, between the one polysilicon pole 17a and the another polysilicon pole 17b, and is smaller than ½ of a spacing, c2, between the another polysilicon pole 17b and the still another polysilicon pole 17c.

As an example, the silicon nitride film 8 is deposited to cover each of the sidewalls and the upper surfaces of the plurality of polysilicon poles 17, and the upper surface of the film 1 to be processed by utilizing the CVD method so that the silicon nitride film 8 having a thickness of 40 nm is formed on each of the sidewalls of the plurality of polysilicon poles 17. As a result, an opening 9 as a depression portion is formed, for example, between the polysilicon pole 17c and the polysilicon pole 17b in a position above the upper surface of the film 1 to be processed. That is to say, the opening 9 as the depression portion having a recess shape is formed in a region surrounded by the four polysilicon poles 17.

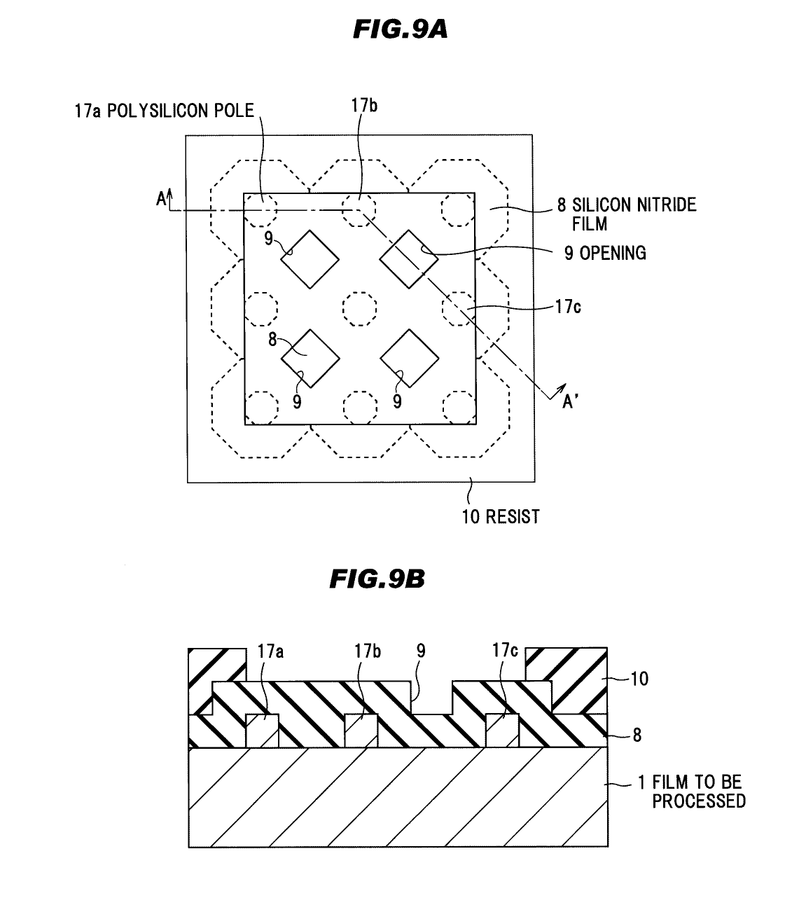

FIG. 9A is a top plan view showing an eighth step following the seventh step of the pattern forming method according to the embodiment of the present invention, and FIG. 9B is a longitudinal cross sectional view showing the eight step of the pattern forming method according to the embodiment of the present invention.

In the eighth step, after a resist 10 is applied to the entire surface of the silicon nitride film 8, a pattern having a predetermined shape is formed in a predetermined region by utilizing the lithography method. Specifically, a pattern of the resist 10 is formed in the predetermined region including a portion in which the polysilicon poles 17 are not located adjacent to one another, more specifically, in the region except for a predetermined region including a portion which is surrounded by the four polysilicon poles 17. That is to say, in the eighth step, the pattern of the resist 10 as a mask material is formed on the silicon nitride film 8 for which no processing will be required in a ninth step which will be described below by utilizing the lithography method.

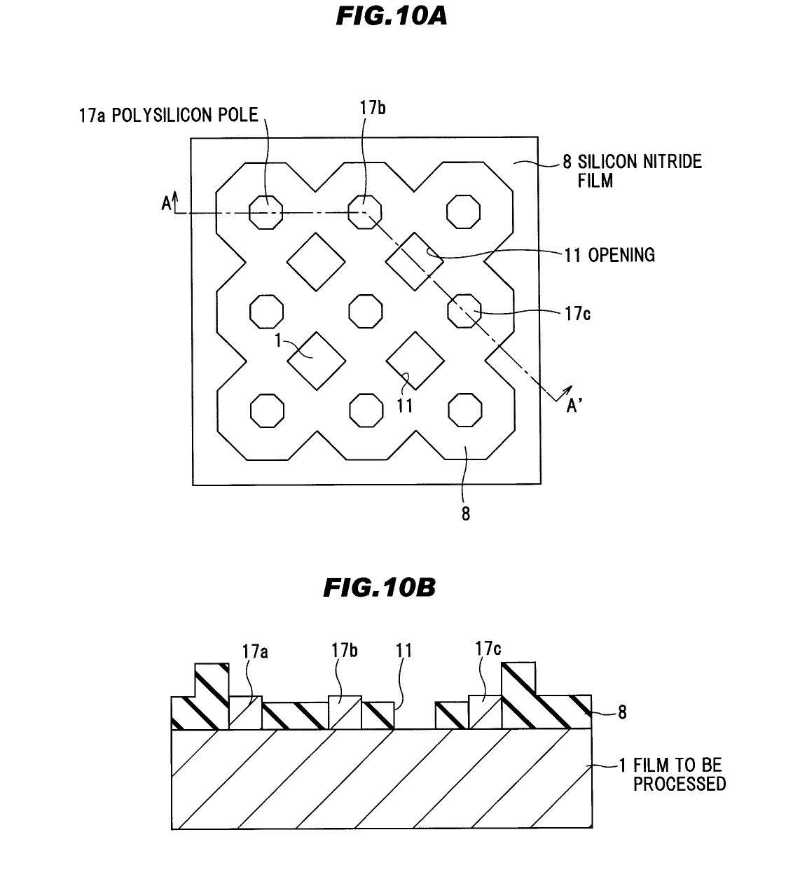

FIG. 10A is a top plan view showing the ninth step following the eight step of the pattern forming method according to the embodiment of the present invention, and FIG. 10B is a longitudinal cross sectional view showing the ninth step of the pattern forming method according to the embodiment of the present invention.

In the ninth step, the silicon nitride film 8 in the region, having no pattern of the resist 10 formed therein, is selectively processed by utilizing a dry etching method, such as the RIE method, using gas such as CH₂F₂. That is to say, the silicon nitride film 8 is dry-etched until the upper surfaces of the plurality of polysilicon poles 17 covered with the silicon nitride film 8 are exposed and also the upper surface portions of the film 1 to be processed 1 corresponding to bottom portions of the openings 9, respectively, are exposed, thereby forming openings 11. Subsequently, after completion of the dry etching, the resist 10 is removed from the silicon nitride film 8 by performing the down flow type plasma ashing processing using O₂ or the like.

It is noted that the silicon nitride film 8 can be selectively dry-etched because an etching rate of each of the polysilicon poles 17 and the film 1 to be processed by the RIE method is lower than that of the silicon nitride film 8 by the RIE method. In addition, since the pattern of the resist 10 is formed in the region which is not surrounded by the four polysilicon poles 17 in the eighth step, the region having the pattern of the resist 10 formed therein is not dry-etched by utilizing the RIE method. Therefore, it is possible to prevent the silicon nitride film 8 from being removed from a portion on the film 1 to be processed from which the silicon nitride film 8 should not be removed.

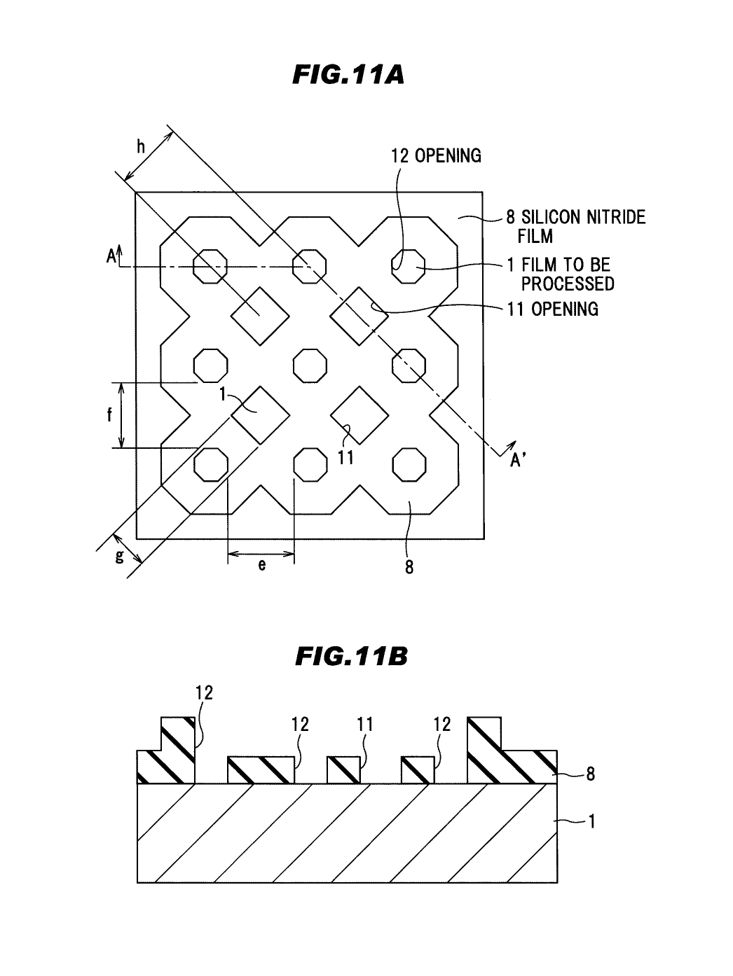

FIG. 11A is a top plan view showing a tenth step following the ninth step of the pattern forming method according to the embodiment of the present invention, and FIG. 11B is a longitudinal cross sectional view showing the tenth step of the pattern forming method according to the embodiment of the present invention.

In the tenth step, the plurality of polysilicon poles 17 exposed after completion of the ninth step are removed. Specifically, the plurality of polysilicon poles 17 are etched away by using an etchant with which an etching rate is higher in polysilicon than in the silicon nitride. As a result, a plurality of openings 11, and a plurality of openings 12 are reliably kept away from each other by the silicon nitride film 8, so that a pattern in which the plurality of openings 11, the plurality of openings 12, or the opening 11 and the opening 12 are not linked to each other is formed on the film 1 to be processed.

Here, each of the plurality of openings 12 is formed in a smaller dimension than that of each of the plurality of openings 4 formed in the first step. Also, a spacing, e, between one opening 12 and another opening 12 in the first direction, and a spacing, f, between the one opening 12 and still another opening 12 in the second direction are enlarged by reduction in dimension of each of the opening 12 from the dimension of each of the openings 4. In addition, a pitch, h, between the opening 11 formed in the position surrounded by the plurality of holes 12, and the opening 12 adjacent to the opening 11 becomes approximately 1/1.4 of the pitch, d, between the adjacent openings 4 formed in the first direction in the first step.

As an example, each of the spacing e and the spacing f is 80 nm, and each of the openings 12 is formed in a dimension such that a circle having a diameter of 40 nm approximately contacts each of the sides of the corresponding one of the openings 12 from the inner side. In addition, each of the openings 11 is formed approximately in a square shape each of sides of which is 40 nm in length. Also, the sum of the number of openings 12 per unit area and the number of openings 11 per unit area becomes double the number of openings 4, per unit area, formed in the first step. After that, although an illustration is omitted here, a pattern having a plurality of holes is formed at pitches, h, in the film 1 to be processed by using the pattern of the silicon nitride film 8 having the openings 11 and the openings 12 as a mask.

According to this embodiment of the present invention, the silicon nitride film is deposited on each of the sidewalls of the plurality of polysilicon poles which are formed at the predetermined intervals on the film to be processed, respectively, and the new opening can be formed in each of the regions surrounded by the corresponding ones of the polysilicon poles. As a result, the dimension of each of the formed openings can be reduced as compared with the case where the openings are formed by utilizing the lithography method, and it is possible to form the openings the number of which is hardly obtained per unit area by utilizing the lithography method.

### (Modifications)

It is noted that the disposition of the plurality of openings 4 formed in the first step is by no means limited to that described in the embodiment. For example, the plurality of openings 4 may be disposed in such a way that the spacing, a1, between one opening 4 and another opening 4 in the first direction, and the spacing, b1, between the one opening 4 and still another opening 4 in the second direction are made different from each other. That is to say, when the spacing between the openings 4 located adjacent to each other in the third direction held between the first direction and the second direction is set as c1, a relationship of the spacing a1<the spacing b1<the spacing c1 is set, and under this condition, the polysilicon poles 17 are formed in the positions of the openings 4, respectively. In addition, the thickness of the silicon nitride film 8 formed on each of the sidewalls of the polysilicon poles 17 in the seventh step is set so as not to be smaller than ½ of a spacing, b2, between the polysilicon poles 17 adjacent to each other in the second direction, and so as to be smaller than ½ of the spacing, c2, between the polysilicon poles 17 adjacent to each other in the third direction.

As a result, the opening 9 as the depression portion is formed in the region surrounded by the four polysilicon poles 17. Subsequently, after there is removed the silicon nitride film 8 on the upper surfaces of the polysilicon poles 17, and in the bottom portions of the depression portions, respectively, the polysilicon poles 17 are removed, which results in that the openings 11 and 12 the total number of which is double the number of openings 4, per unit area, formed in the first step can be formed on the film 1 to be processed.

In addition, the method of forming the polysilicon poles 17 at the predetermined intervals on the film 1 to be processed is also by no means limited to that described in the embodiment. For example, a process may also be adopted such that after the pattern of the polysilicon film 7 having the polysilicon poles 17 which will be disposed approximately at the even intervals is directly formed on the film 1 to be processed by utilizing the lithography method, the slimming processing is performed for the polysilicon film 7, thereby forming the plurality of polysilicon poles 17 as the pole-like structures as shown in FIG. 6 on the film 1 to be processed. Or, a process may also be adopted such that after polysilicon is filled in each of the openings formed by transferring the pattern of the openings 4 to the silicon nitride film 2 without reducing the dimension of each of the openings 4, and the silicon nitride film 2 is then selectively removed, the slimming processing is performed for polysilicon left on the film 1 to be processed, thereby forming the polysilicon poles 17 on the film 1 to be processed.

Although the embodiment of the present invention has been described so far, it should be noted that the embodiment described above limits by no means the present invention disclosed in the appended claims. In addition, all the combinations of the features described in the embodiment are not necessarily essential to the means for solving the problems that the present invention is to be solved.

What is claimed is:

1. A pattern forming method comprising:
forming a plurality of pole-like structures above a film to be processed;
forming a sidewall film on each of sidewalls of the plurality of pole-like structures so as to form a depression portion in a region surrounded by corresponding ones of the plurality of pole-like structures;
removing the sidewall film formed above each of the plurality of pole-like structures and in a bottom portion of the depression portion, respectively, by performing etching; and
selectively etching the plurality of pole-like structures with the sidewall film being left.

2. The pattern forming method according to claim 1, wherein forming the plurality of pole-like structures comprises:
forming a pattern including a plurality of first openings in a first material film formed above the film to be processed;
filling a second material film in each of the plurality of first openings; and
selectively etching the first material film with the second material film filled in each of the plurality of first openings being left.

3. The pattern forming method according to claim 2, wherein in forming the pattern including the plurality of first openings, the plurality of first openings are formed in the first material film at predetermined intervals along a first direction and a second direction vertical to the first direction;
in selectively etching the first material film, the plurality of pole-like structures each being formed from the second material film are left above the film to be processed at predetermined intervals along the first direction and the second direction; and
in forming the sidewall film on each of the sidewalls of the plurality of pole-like structures, the sidewall film is formed on the sidewall of a first pole-like structure in the plurality of pole-like structures, and on the sidewall of a second pole-like structure located adjacent to the first pole-like structure along a third direction held between the first direction and the second direction so that the depression portion is formed between the first pole-like structure and the second pole-like structure.

4. The pattern forming method according to claim 3, wherein in forming the sidewall film on each of the sidewalls of the plurality of pole-like structures, the sidewall film is formed to have a thickness such that the sidewall film formed on the sidewall of the first pole-like structure, and each of the sidewall film formed on the sidewall of a third pole-like structure, and the sidewall film formed on the sidewall of a fourth pole-like structure contact each other, the third pole-like structure and the fourth pole-like structure being located adjacent to the first pole-like structure along the first direction and the second direction, respectively, and the sidewall film formed on the sidewall of the first pole-like structure, and the sidewall film formed on the sidewall of the second pole-like structure do not contact each other.

5. The pattern forming method according to claim 2, wherein forming the pattern including the plurality of first openings comprises:
applying a resist to the first material film;
forming a resist pattern having a plurality of second openings each of which is larger in dimension than each of the plurality of first openings in the resist by utilizing a lithography method;
enlarging a dimension of the resist to reduce the dimension of each of the plurality of second openings to the dimension of each of the plurality of first openings; and
causing the pattern including the plurality of first openings transferred to the first material film by etching the first material film by using a resist pattern having the plurality of second openings as a mask, the dimension of each of the plurality of second openings having been reduced to the dimension of each of the plurality of first openings.

6. The pattern forming method according to claim 4, wherein in forming the sidewall film on each of the sidewalls of the plurality of pole-like structures, the sidewall film is formed to have a thickness which is not smaller than ½ of each of a spacing between the first pole-like structure and the third pole-like structure, and a spacing between the first pole-like structure and the fourth pole-like structure, and is smaller than ½ of a spacing between the first pole-like structure and the second pole-like structure.

7. The pattern forming method according to claim 3, wherein in forming the pattern including the plurality of first openings, the plurality of first openings are disposed substantially at even intervals in the first direction and in the second direction in the first material film.

8. The pattern forming method according to claim 7, wherein in forming the pattern including the plurality of first openings, the plurality of first openings are disposed in a matrix in the first direction and in the second direction in the first material film.

9. The pattern forming method according to claim 5, wherein reducing the dimension of each of the plurality of second openings to the dimension of each of the plurality of first opening comprises:
forming a reaction layer obtained by hardening a pattern shrink material by performing a heating treatment on a surface of the resist after the pattern shrink material is applied to the surface of the resist; and
removing the pattern shrink material which is not hardened by performing the heating treatment.

10. The pattern forming method according to claim 2, wherein forming the pattern including the plurality of first openings comprises:
applying a resist to the first material film;
forming a resist pattern having a plurality of second openings each of which is larger in dimension than each of the plurality of first openings in the resist by utilizing a lithography method;
forming sidewalls on side surfaces of the plurality of second openings of the resist, respectively, thereby reducing the dimension of each of the plurality of second openings to the dimension of each of the plurality of first openings; and
causing the pattern including the plurality of first openings transferred to the first material film by etching the first material film by using the resist pattern and the sidewalls as a mask.

11. The pattern forming method according to claim 2, wherein filling the second material film in each of the plurality of first openings comprises:
depositing the second material film on the first material film having the pattern including the plurality of first openings; and
planarizing the second material film deposited on the first material film having the pattern including the plurality of first openings.

12. The pattern forming method according to claim 11, wherein in planarizing the second material film deposited on the first material film having the pattern including the plurality of first openings, the planarization is performed for the second material film until at least a surface of the second material film located in each of the plurality of first openings is exposed.

13. The pattern forming method according to claim 2, wherein in selectively etching the first material film, the first material film above the film to be processed is selectively removed by utilizing an RIE method.

14. The pattern forming method according to claim 2, wherein in selectively etching the first material film, the first material film is selectively wet-etched by using an etchant with which an etching rate is higher in the first material film than in the second material film.

15. The pattern forming method according to claim 1, wherein in selectively etching the plurality of pole-like structures with the sidewall film being left, the plurality of pole-like structures are selectively etched by using an etchant with which an etching rate is higher in each of the plurality of pole-like structures than in the sidewall film.

16. The pattern forming method according to claim 1, further comprising: forming a mask material in a region where the plurality of pole-like structures are not adjacently located between forming the sidewall film on each of the sidewalls of the plurality of pole-like structures and removing the sidewall film by performing the etching.

17. The pattern forming method according to claim 2, wherein in forming the pattern including the plurality of first openings, the plurality of first openings are disposed in the first material film along a first direction and a second direction vertical to the first direction in such a way that a spacing between one opening and another opening of the plurality of first openings in the first direction is made different from that between the one opening and still another opening of the plurality of first openings in the second direction.

18. The pattern forming method according to claim 1, wherein the film to be processed is a silicon oxide film or a Low-k film.

19. The pattern forming method according to claim 2, wherein the first material film is a silicon nitride film.

20. The pattern forming method according to claim 2, wherein the second material film is a polysilicon film.
